(19) United States
(12) Patent Application Publication
(10) Pub. No.: US 2015/0144175 A1
(43) Pub. Date: May 28, 2015

(54) PHOTOVOLTAIC MODULE WITH PHOTOVOLTAIC CELLS HAVING LOCAL WIDENING OF THE BUS

(71) Applicant: COMMISSARIAT A L'ENERGIE ATOMIQUE ET AUX ENERGIES ALTERNATIVES, Paris (FR)

(72) Inventor: Armand Bettinelli, Courblevie (FR)

(21) Appl. No.: 14/402,383

(22) PCT Filed: May 17, 2013
(86) PCT No.: PCT/EP2013/060219

§ 371 Date: Nov. 20, 2014

(30) Foreign Application Priority Data
May 21, 2012 (FR) 12 54609

(51) Int. Cl. H01L 31/02; H01L 31/18

(52) U.S. Cl. CPC H01L 31/0201; H01L 31/18
USPC 136/244; 438/67

(57) ABSTRACT

A photovoltaic module has cells each having at least one collecting finger (2) oriented in a first elongation direction (D1) and at least one bus (3) oriented in a second elongation direction (D2) making at an angle to the first. At a zone (4) of electrical connection between the bus (3) and the collecting finger (2), the bus has at least one local enlargement (Le) of its width (Lb) along the first direction (D1). The ratio of the length (We) in the second direction (D2) of the local enlargement (Le) of the width (Lb) of the bus (3) to the width (Wd) of the corresponding collecting finger (2) in the second direction (D2) is strictly higher than one. The total width (Lt) of the bus at a local enlargement (Le) is strictly larger than the width (Lr) along the first direction of a metal strip (5) that electrically connects the cells.

### TECHNICAL FIELD OF THE INVENTION

The invention relates to a photovoltaic module comprising a plurality of photovoltaic cells that are electrically connected to one another by way of at least one metal strip interconnected with at least one bus of the photovoltaic cells.

Another subject of the invention is a process for manufacturing such a photovoltaic module.

### PRIOR ART

Ways of improving the performance of photovoltaic cells are continuously being researched. One of the aims of such research is to increase the efficiency of the conversion of received light into electrical power while limiting as much as possible the conversion cost in order to obtain the best possible available power/generation cost ratio. This ratio may be obtained by improving the performance of the photovoltaic cells and/or by decreasing their cost.

Photovoltaic cells are conventionally manufactured using a substrate wafer made of a semiconductor, generally silicon. Their manufacture in particular requires electrical conductors to be formed on the surface of this substrate. FIG. 1 illustrates the front side of such a substrate 1 according to the prior art, which comprises parallel first conductors oriented in a first elongation direction D1, each conductor having a relatively thin width measured perpendicularly to their elongation direction D1. These conductors, referenced 2, are called “collecting fingers” or “collecting combs”, and their function is to collect the electrons created by the light in the silicon of the substrate 1. The front side of the substrate 1 in addition comprises parallel second conductors oriented in a second elongation direction D2. They are referred to as “buses” or “busbars” and have been given the reference number 3. The function of a bus 3 is to gather and conduct electrical charge from the collecting fingers 2, to which they make electrical contact at electrical connection zones 4. More generally, a given bus 3 is associated with a plurality of collecting fingers 2 at corresponding electrical connection zones 4 that are spaced out along the length of the bus 3, and the electrical charge conducted by the bus 3 is therefore greater than that conducted by each collecting finger 2. The bus 3 has a width, measured perpendicularly to its elongation direction D2, clearly larger than the width of the collecting fingers 2. The buses 3 are especially oriented in an elongation direction D2 perpendicular to the elongation direction D1 of the collecting fingers 2.

In general, each bus 3 is furthermore electrically and mechanically interconnected with a metal strip 5, especially one made of copper, extending over all of some of its length. In order to produce such a continuous or optionally discontinuous interconnection over the length of the bus 3, the metal strip 5 may be connected to the bus 3, by an electrically conductive fastening means 6 such as a solder or a conductive adhesive (conductive glue or conductive adhesive film), over all or some of the length of the bus 3 in the direction D2. The metal strip 5 therefore also extends in D2 and theoretically covers the entire width of the bus 3 along D1. One metal strip 5 is intended to electrically connect a plurality of photovoltaic cells to one another. A photovoltaic module is therefore conventionally made up of a plurality of photovoltaic cells and of at least one metal strip 5 interconnected with at least one bus of these cells so as to electrically connect the cells to one another.

To produce these conductors (collecting fingers 2 and buses 3), one method known in the art, called the “single print” method, consists in depositing a conductive ink by screen printing on the substrate 1, by way of a screen-printing operation in which the buses 3 are conjointly formed with the collecting fingers 2. Generally, the width Lb of the buses 3 is equivalent to the width Lr of the metal strips 5 in order not to create additional shadowing with respect to the light received by the front side of the substrate 1. However, as illustrated in FIG. 2, the alignment of the metal strips 5 relative to the buses 3 and the collecting fingers 2 is liable in practice to be imperfect in the plane of the directions D1 and D2. One of the edges of the metal strip 5 may especially be offset Δ in the direction D1 relative to the bus 3 with which it is interconnected, so that this edge of the metal strip 5 is located plumb with (as considered in the direction perpendicular to the plane of the front side of the substrate 1, therefore perpendicularly to the directions D1 and D2) a portion 7 of the collecting fingers 2. These portions 7 of collecting fingers 2 are subject to stresses during the step of interconnecting the bus and the strip and there is therefore a risk, for example, of them being partially deteriorated during the operation of soldering the strip 5 or, in the case of interconnection by means of a conductive adhesive film, because of the high pressure applied. Burrs that may be present on the corners of metal strips 5 of rectangular cross section may accentuate the stresses exerted on the collecting fingers 2.

The portions 7 of the collecting fingers 2 are also subjected to stresses during the life of the photovoltaic module. For example, temperature variations have the effect of creating stresses due to differential expansion between the photovoltaic cell and the interconnected metal strips 5. Thus, repeated thermal cycles may degrade the performance of the modules, such degradation especially taking the form of discontinuities in the collecting fingers 2 in line with the edge of the metal strips in the case where said strips are offset Δ relative to the bus 3. The probability of this effect being observed increases if the width of the collecting fingers 2 is decreased, if the strips 5 comprise burrs and if the strips 5 are large in thickness. The low-temperature pastes used to manufacture heterojunction photovoltaic cells and the absence of high-temperature bakes engendered by the use of such pastes make the collecting fingers 2 even more fragile and increase the probability of degradation over time.

Now, a prior-art improvement consists precisely in making the metallisations corresponding to the collecting fingers 2 as narrow as possible. Decreasing the width of the collecting fingers 2 allows the current produced by the photovoltaic cell to be increased by decreasing the shadowing seen by the light with respect to the substrate 1. It also advantageously allows the amount of material consumed forming the collecting fingers 2 to be decreased, which is important in the current climate of increasing prices of raw materials such as silver for example. However, the collecting fingers 2 must be sufficiently thick to prevent their resistivity from becoming too high. With a “single print” process, such a constraint means that the thickness of the bus 3 is also increased. A very large amount of material is therefore consumed.

For this reason, another known prior-art method consists in printing the conductive elements, i.e. the collecting fingers 2 and the buses 3, in two steps.

A first technique, with reference to FIG. 3, called the “double print” technique, consists of printing the collecting fingers 2 in two superposed operations, the buses 3 being printed in only one of these two printing operations in order to limit the consumption of material. The “double print” technology advantageously allows the ratio of the width of the collecting fingers 2 to their height to be increased but it requires perfect alignment of the two levels produced in the superposed printing operations.

A second technique, with reference to FIG. 4, called the “dual print” technique consists in printing all of the collecting fingers alone in a first step, followed by another subsequent printing operation in which only the buses 3 are printed. The “dual print” technology advantageously allows the rheological constraints of printing narrow buses 3 to be limited and thus less expensive pastes, optimised only in terms of adhesion and solderability, to be used, these pastes being deposited with a minimum thickness. Resistance constraints are low since the metal strips 5 are interconnected. The precision required with regard to the alignment of the two printing operations is also clearly lower.

In the “double print” and “dual print” technologies, as illustrated in FIGS. 3 and 4, issues arise with irregularities in the thickness of the metallisations (collecting fingers 2 and/or buses 3) in the zone of interconnection between the buses 3 and the metal strips 5. Specifically, the quality and reliability of the interconnection between the metal strip 5 and the metallisations may be affected by these thickness irregularities as they cause stresses to be irregularly distributed after the metal strip 5 has been fastened by soldering or adhesive bonding.

In the “dual print” technology in particular, connection of the collecting fingers 2 and the buses 3 becomes problematic. This is not directly the case if the collecting fingers 2 are continuous through the electrical connection zone 4 and on either side of the latter along the first direction D1, or if they extend far enough under a zone of contact with the bus 3.

However, in these two cases, the connection induces a thickness irregularity that is particularly disadvantageous for the interconnection of the metal strip 5. It remains possible to work around such thickness irregularities by positioning the zone of contact between the bus and the collecting finger outside of the zone of interconnection between the bus and the metal strip. However, the precision of the alignment of the two printing operations then becomes an essential parameter.

Lastly, as regards the question of decreasing the amount of material used, one envisaged technique, with reference to FIG. 5, consists in making provision for the width of the bus 3 to be clearly smaller than the width of the metal strip 5 intended to be interconnected. Such a technique is particularly advantageous when used in the manufacture of heterojunction photovoltaic cells as heterojunction photovoltaic cells require material pastes to be deposited with large thicknesses, because of the higher resistivity of low-temperature pastes. In the case where the strip and the bus are interconnected by solder, the area of the buses 3 must remain sufficiently large to ensure the mechanical adhesion of the soldered strips. In the case where the strip and the bus are interconnected by adhesive bonding, the area of the buses 3 may be more greatly decreased, the only proviso being that the desired contact resistances be obtained. Specifically, constraints on mechanical adhesion are not greatly impacted since adhesive bonding also occurs in non-conductive zones. The use of buses 3 narrower than the strips 5 implies that the stresses on the collecting fingers 2 plumb with the edges of the strips 5 are then systematic and high in the zones referenced 8. FIGS. 6 and 7 illustrate identical issues in “double print” and “dual print” printing technologies, respectively, especially again with the appearance again of thickness irregularities. Now such irregularities in the planarity of the metallisations are particularly disadvantageous, with respect to interconnection reliability, when the bus 3 is small in width.

Documents JP 2009272405 and KR 20110018659 provide for local enlargement of the bus at each collecting finger but do not describe connection of various cells.

### OBJECTIVE OF THE INVENTION

Thus, one general objective of the invention is to provide a photovoltaic module and a manufacturing process that address the aforementioned issues while addressing the general issues of cost and performance.

More precisely, another objective of the invention is to provide a solution allowing the reliability of the photovoltaic cell and/or the photovoltaic module to be improved independently of the width of the collecting fingers and/or buses.

Another objective of the invention is to provide a solution allowing the mechanical stresses experienced by the collecting fingers to be limited.

Another objective of the invention is to provide a solution allowing the mechanical and electrical interconnection between the buses and the metal strips to be made more reliable.

Another objective of the invention is to make it easier to manufacture the photovoltaic module and especially to interconnect the buses and the metal strips.

These objectives are achieved by the appended claims.

### BRIEF DESCRIPTION OF THE DRAWINGS

Other advantages and features will become more clearly apparent from the following description of particular embodiments of the invention, given by way of nonlimiting example and shown in the appended drawings, in which:

FIG. 1 schematically illustrates collecting fingers and buses on the surface of a photovoltaic cell according to the prior art;

FIGS. 2 and 5 show two known examples of application of the “single print” technology;

FIGS. 3 and 6 show two known examples of application of the “double print” technology;

FIGS. 4 and 7 show two known examples of application of the “dual print” technology;

FIG. 8 shows a first embodiment of the invention, using the “single print” technology;

FIG. 9 shows a second embodiment of the invention, using the “double print” technology;

FIGS. 10 and 11 show third and fourth embodiments of the invention, using the “dual print” technology;

FIG. 12 schematically shows the zone of electrical connection between the bus and collecting finger in the first embodiment; and

FIG. 13 schematically shows the zone of electrical connection between the bus and collecting finger in the second, third and fourth embodiments.

### DESCRIPTION OF PREFERRED EMBODIMENTS OF THE INVENTION

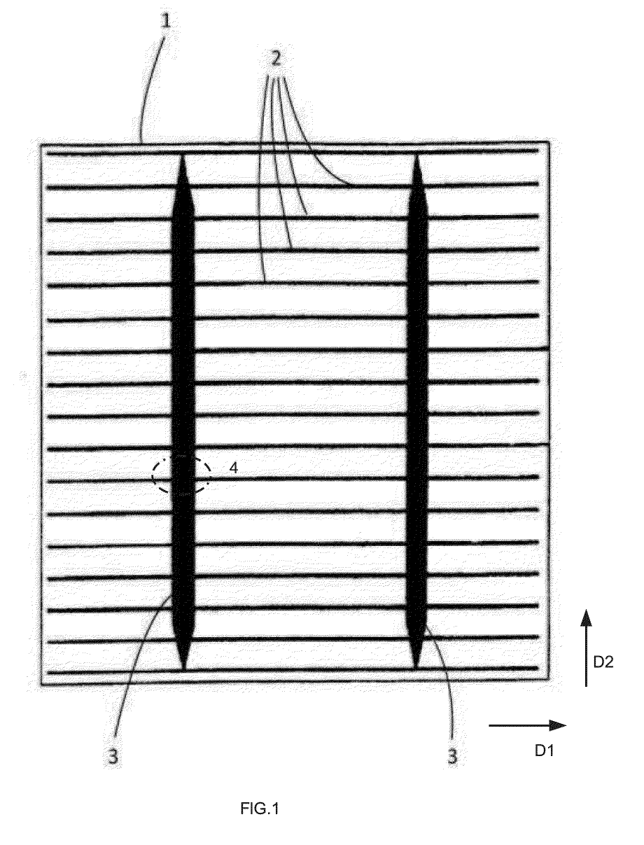

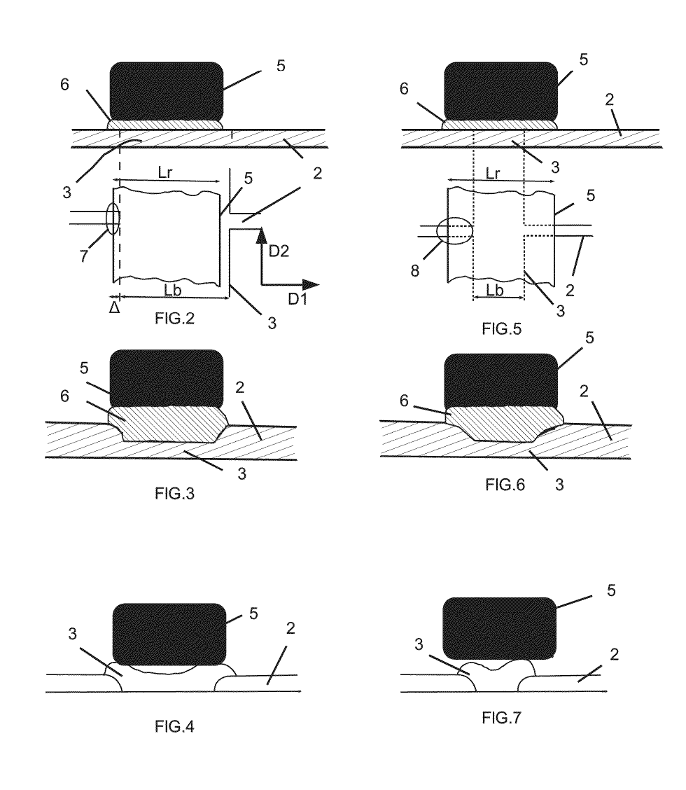

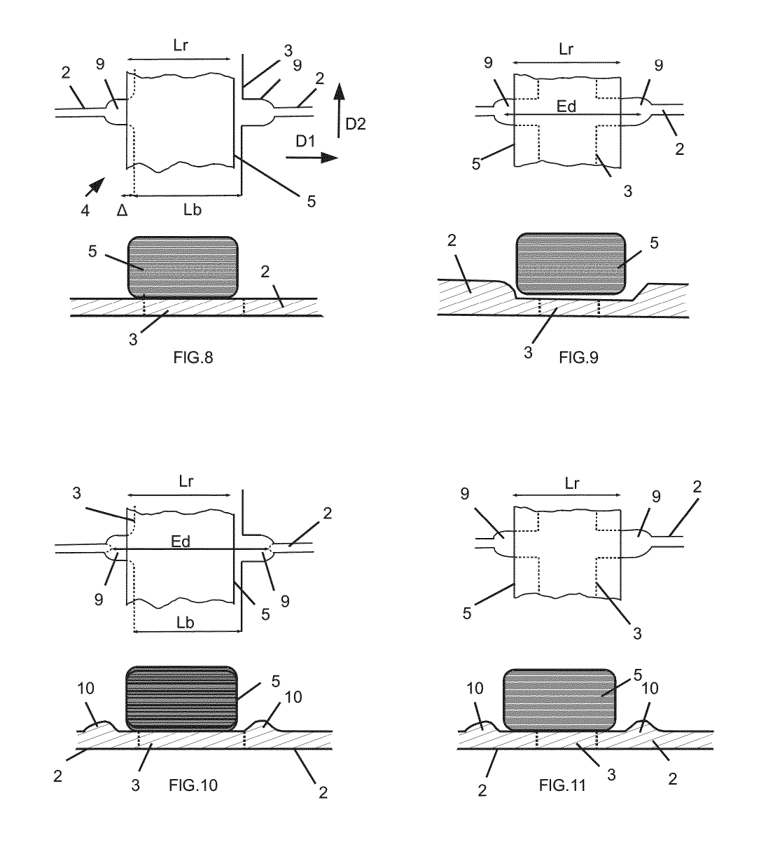

With reference to FIGS. 8 to 13, a photovoltaic cell comprises electrically conductive metallisations, for example based on silver, on a front side of a substrate wafer 1 made of a semiconductor, generally silicon. The metallisations could also be based on copper and especially silver-coated copper. The references defined in the description of FIGS. 1 to 7 have been preserved for identical elements. Collecting fingers 2, in particular continuous collecting fingers 2, are formed parallel to one another, in the first elongation direction D1. Their width “Wd” is considered perpendicularly to their elongation direction D1 and their width “Wd” is, in particular, substantially constant along the first elongation direction D1. Their function is to collect the electrons created by light in the silicon of the substrate 1.

The front side of the substrate 1 also comprises at least one bus 3, even a plurality of such buses 3 parallel to one another, each bus being oriented in the second elongation direction D2. The buses 3 are, more particularly, each continuous. The function of a bus 3 is to gather and conduct electrical charge from the collecting fingers 2. Each collecting finger 2 is therefore connected to a bus 3 at a bus/collecting finger electrical connection zone 4. More generally, since a given bus 3 is associated with a plurality of collecting fingers 2 at various electrical connection zones 4 that are spaced out, in D2, along the length of the bus 3, the electrical charge conducted by the bus 3 is greater than that conducted by each collecting finger 2. The bus 3 therefore has a width “Lb”, considered perpendicularly to its elongation direction D2, clearly larger than the width “Wd” of the collecting fingers 2. The buses 3 are especially oriented in an elongation direction D2 making an angle, especially 90°, to the elongation direction D1 of the collecting fingers 2. In this particular case, the width Wd is measured along the direction D2 and the width Lb is measured along the direction D1.

At the zone 4 of the electrical connection between the bus 3 and the collecting finger 2, the bus 3 comprises at least one local enlargement “Le” of the width “Lb” of the bus 3 along the first elongation direction D1. Thus, the width “Lb” of a bus 3 is, more particularly, considered to be constant along the second elongation direction D2, except for at least one local enlargement “Le” located at a zone 4 of the electrical connection with one or more collecting fingers 2. A local enlargement, denoted “Le”, takes the form of a protuberance 9 formed in the bus 3, in the plane (D1, D2), along the direction D1, so as to stick out from the edge of the bus oriented along D2. Moreover, the local enlargement “Le” of the bus 3 has a length (We) in the second elongation direction D2 strictly greater than the width (Wd) of the corresponding collecting finger 2 in the second direction D2.

In the illustrated variant, the bus 3 comprises an enlargement “Le” at its intersection with each of the collecting fingers 2. It therefore comprises two enlargements formed on its two edges that define the width Lb, respectively. However, the bus 3 could comprise only a single enlargement Le formed sticking out from only one of its two edges, especially in the case where only one collecting finger 2 is connected to the bus in the electrical connection zone 4.

When photovoltaic cells are electrically connected together with a view to manufacturing a photovoltaic module made up of a plurality of interconnected cells, the photovoltaic cell receives at least one metal strip 5, especially one made of copper, which at least partially covers the bus 3 while being mechanically and electrically connected to the bus 3, by way of an electrically conductive fastening means 6 such as a solder or adhesive conductor, over all or some of the length of the bus 3. The metal strip 5 is oriented along the second direction D2 over the entire length of the substrate 1 and beyond the substrate 1 in order to allow a plurality of photovoltaic cells to be electrically connected to one another. It is a question of implementation of an interconnection step in which the metal strip is interconnected with at least one of said at least one buses of the photovoltaic cell in question. It may for example be a question of an adhesive-bonding interconnection step and/or a soldering interconnection step.

Whatever the ratio of the width “Lr” of the strip 5 to the width “Lb” of the bus, the total width “Lt” of the bus 3 at a local enlargement of the bus 3, i.e. at the electrical connection zone 4, is larger than the width Lr of the metal strip 5 along the first direction D1. This feature has the advantage of allowing a better mechanical adhesion and electrical performance to be obtained with the metal strip on the metallisation, i.e. on the buses 3 and/or collecting fingers 2, making it possible to increase the reliability of the bus/strip interconnections and to increase the quality of the bus/strip interconnections.

To maximise reliability with regard to current bus/strip alignment precision, the difference between the total width Lt of the bus at a local enlargement Le and the width Lr of the metal strip is advantageously larger than 400 microns. This difference of at least 400 microns may be equally distributed on either side of the bus 3 along the direction D1. It should be noted that the width Lr of the strip 5 is considered perpendicularly to its elongation direction, which here coincides with the direction D2.

Providing at least one such enlargement “Le” taking the form of a protuberance 9 from the bus 3 in D1 advantageously makes it possible:
to increase the reliablity of the interconnection between the bus 3 and a metal strip 5 of width “Lr” intended to be mechanically and electrically connected to the bus 3;
to limit the stresses experienced by the collecting fingers 2, in the case of where an offset Δ is present between the strip 5 and the bus 3 along the direction D1 (FIGS. 8 and 10) and/or in the case where the width Lr of the strip 5 is intentionally clearly larger than the width Lb of the bus 3 (FIGS. 9 and 11 to 13); and
to decrease the precision possibly required for alignment in the case of a metallisation produced in at least two steps.

Advantageously, the photovoltaic cell comprises a plurality of collecting fingers 2 formed on the front side of the substrate 1. In particular, the smaller the width Wd of the collecting fingers 2, the greater the number of collecting fingers 2. Each collecting finger 2 is then electrically connected to a bus 3 in an associated electrical connection zone 4 so that the bus 3 electrically connects the collecting fingers 2 to one another along the direction D2 between the electrical connection zones 4. In the way illustrated, each of the electrical connection zones 4 between the bus 3 and the collecting fingers 2 comprises a local enlargement of the width of the bus 3 taking the form of a protuberance 9 oriented in D1 from the side of the collecting finger 2. A given enlargement of the bus 3 is associated, on a given side of the bus 3 along the first direction D1, with a single collecting finger 2. The total width “Lt” of the bus 3, at the local enlargement of any electrical connection zone 4, is larger than the width Lb of the bus 3 outside of the electrical connection zones 4. Advantageously, the ratio of the width Lt of the bus 3 at a local enlargement of its width to the width Lb of the bus 3 outside of the electrical connection zones 4 is higher than 1.25. To maximise reliability with regard to current bus/strip alignment precision, the difference between the width Lt of the bus 3 at a local enlargement of its width and the width Lb of the bus outside of the electrical connection zones may advantageously be larger than 400 microns. For this purpose, it is possible to make provision for each of the two possible protuberances 9 on either side of the bus 3 to be larger than about 200 microns and even 250 microns in size along the direction D1.

In the first and third embodiments in FIGS. 8 and 10, respectively, the width Lb of the bus 3 is substantially equal to the width Lr of the metal strip 5 in order to prevent as much as possible the strip 5 from having a shadowing effect with respect to the light received by the front side of the substrate 1. However, as illustrated in FIG. 8, the alignment of the metal strip 5 relative to the bus 3 is liable to be imperfect in the direction D1. One of the edges of the metal strip 5 may especially be offset Δ in the direction D1 relative to the bus 3 with which it is interconnected. This edge of the metal strip 5 is then advantageously located plumb with (as considered in the direction perpendicular to the plane of the front side of the substrate 1, therefore perpendicularly to the directions D1 and D2) a constituent protuberance 9 of the local width enlargement of the bus 3. This makes it possible to prevent any risk of direct connection between the metal strip 5 and the collecting fingers 2 and to limit the stresses experienced by the collecting fingers 2 in the step of interconnecting the bus 3 and the metal strip 5.

In the second and fourth embodiments in FIGS. 9 and 11, respectively, the width Lb of the bus 3 outside of the electrical connection zones 4 is clearly smaller than the width of the metal strip 5. In particular, the ratio of the width Lr of the strip 5 and the width of the bus 3 is advantageously higher than two and preferably higher than 4, thereby allowing the amount of metal deposited to be greatly decreased. FIGS. 9 and 11 illustrate that the protuberances 9 are clearly much larger along the first direction D1 than is the case in FIGS. 8 and 10 in order to guarantee that the total width Lt of the bus 3 at the local enlargement of the bus 3, i.e. at the electrical connection zone 4, is nonetheless larger than the width Lr of the metal strip 5 along the first direction D1 despite the small width Lb of the bus 3.

Whereas the dimension measured along the direction D1 of a local enlargement of the bus 3 is referenced “Le”, the length in the second direction D2 of the local enlargement “Le” of the width of the bus 3 is referenced “We”. Advantageously, in order to obtain a satisfactory resistance at the connection between the collecting finger 2 and the bus 3, the length We along D2 of the local enlargement of the bus 3 is larger than or equal to 150 microns, independently of the width Wd of the collecting finger 2. Moreover, or alternatively, depending on the process used to form the metallisations, in the case where the collecting finger 2 has a very small width Wd (for example of about a few tenths of a millimeter), the ratio of the length We to the width Wd of the corresponding collecting finger 2 in the second direction D2 is higher than two.

Generally, the manufacture of a photovoltaic module such as described above comprises a step of metallising a substrate 1, carried out so as to form at least one collecting finger 2 oriented in D1 and at least one bus 3 oriented in D2 that comprises at least one local enlargement Le of its width along D1, then a step of interconnecting said at least one metal strip 5 and at least one bus 3.

In particular, for a given photovoltaic cell, the metallisation step may consist in a single step in which said at least one collecting finger 2 and said at least one bus 3 are conjointly formed. Alternatively, said metallisation step may also be carried out in a number of steps. In particular, it may be formed by a first step in which only said at least one collecting finger 2 is produced on the substrate 1, and by a second step in which only said at least one bus 3 is produced on the substrate 1 and covering a portion of the collecting finger 2 in the electrical connection zone 4. According to one alternative, the metallisation step may comprise a first step in which a first layer of said at least one collecting finger 2 is produced on the substrate 1, and a second step in which the following are conjointly formed:
said at least one bus 3 on the substrate 1 and covering a portion of the first layer of the collecting finger 2 in the electrical connection zone 4; and
a second layer of said at least one collecting finger 2 on its first layer.

Although any technique known in the art may be used to produce the metallisation (whether in the case of a metallisation process of a single step or of a number of steps), the latter may in particular be produced by screen printing an ink on the substrate 1.

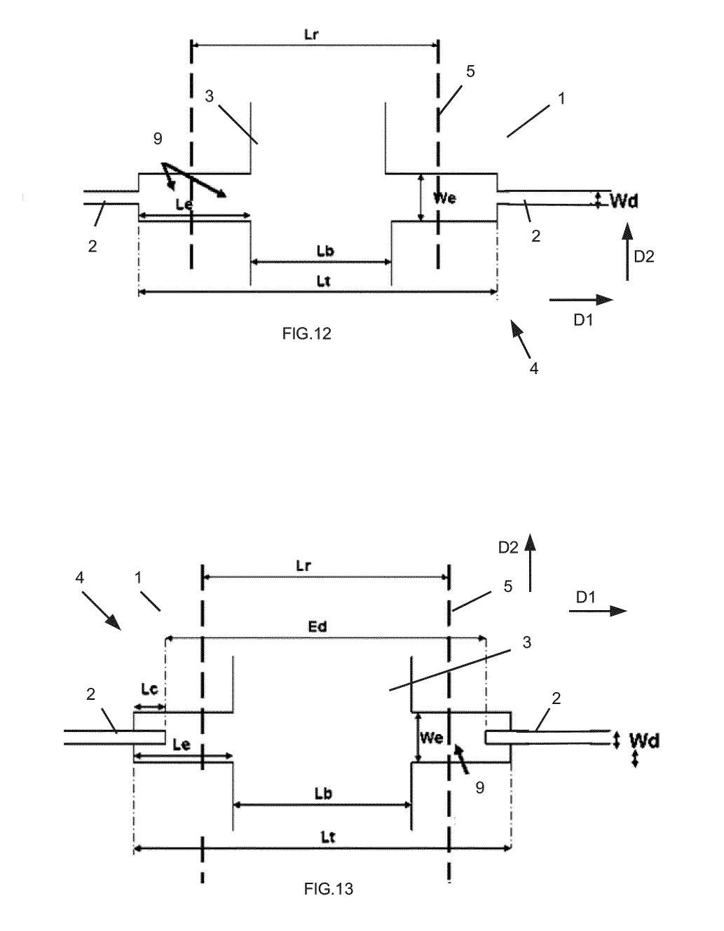

With reference to FIG. 12, the metallisation step may comprise a single step, in particular carried out by screen printing, in which step the collecting finger(s) 2 and the bus(es) 3 are conjointly formed. Such a technique, called the “single print” technique, is used to achieve the layout in FIG. 8 for example.

Alternatively, the metallisation step may preferably comprise, with reference to FIG. 13, at least two successive steps, in particular two successive screen-printing steps, thereby especially allowing collecting fingers 2 having smaller widths Wd than those that can be obtained using “single print” technology to be obtained.

In a first possible solution, called the “dual print” solution, the metallisation step comprises a first screen-printing step in which only the collecting finger(s) 2 is (are) produced on the substrate 1 and a second screen-printing step in which only the bus(es) 3 is (are) produced on the substrate 1. In the second screen-printing step, the bus(es) 3 is (are) produced covering a portion of the collecting finger 2 in the electrical connection zone 4 in order to ensure the electrical connection of the collecting finger 2 and the bus 3. The overlap occurs at the protuberances 9 formed in order to enlarge the bus 3 in the direction D1, which has the effect of forming bumps 10 that furthermore have the advantage of having no incidence on the strip/bus interconnection because the bumps 10 are located outside of the strip/bus interconnection zone. Such a “dual print” technique is used to achieve the layout in FIGS. 10 and 11.

In particular, the first printing step may be carried out so that the collecting finger 2 is discontinuous, an interruption being provided at its zone 4 of electrical connection to the bus 3. The collecting finger comprises at least two segments aligned in the first direction D1 having interposed between them a space “Ed” (FIGS. 10 and 13) in the first direction D1. Advantageously, the first and second screen-printing steps are carried out so that the total width Lt of the bus 3 at the local width enlargement of the bus 3 is larger than the space Ed between the two segments of collecting finger 2. Preferably, the difference between the width Lt of the bus and the space Ed is especially larger than 200 microns and equally distributed on either side of the bus 3 along the first direction D1. Thus, each protuberance 9 extends along the first direction D1 across segments of collecting fingers 2 over a length referenced “Lc” larger than about 100 microns. However, it remains envisageable for the collecting finger 2 formed in the first screen-printing step to be continuous along the direction D1 right through the electrical connection zone 4, the bus 3 formed in the second step then being intended to cover all of this continuous portion of collecting finger 2.

Moreover, the first and second screen-printing steps are carried out so that the difference between the width Wd of the collecting finger 2 and the length We in the second direction D2 of the local enlargement of the width of the bus 3 is also larger than 100 microns. As shown and nonlimitingly this difference between We and Wd may be distributed, especially equally, on either side of the collecting finger 2 along the second direction D2.

Thus, because there is no metallisation in the space Ed, it is possible for the metallisation of the buses 3 at their enlargement “Le” to be deposited with a well-controlled regular thickness because, when the screen printing of the bus is carried out after the screen printing of the collecting fingers 2 alone, the screen used makes a good contact, which is important if the cost of the, especially silver, pastes used for the metallisations is to be minimised, and participates in the quality of the interconnection between the strips 5 and the buses 3.

In a second possible solution, called the “double print” solution, the metallisation step comprises a first screen-printing step, in which a first layer of the collecting finger 2 is produced on the substrate 1, and a second screen-printing step in which the following are conjointly formed:
the bus 3 on the substrate 1 and covering a portion of the first layer of the collecting finger 2 in the electrical connection zone 4; and
a second layer of the collecting finger 2 on its first layer.

The first and second layers of the collecting fingers 2 are superposed in the direction perpendicular to the plane of the substrate 1 and make electrical contact with each other. The bus 3 overlaps the first layer of the collecting finger 2 at the protuberances 9 formed in order to enlarge the bus 3 in the direction D1 in the second step. Such a “double print” technique is used to achieve the layout in FIG. 9 for example, the thickness of the collecting fingers 2 being larger than that of the buses, the transition between the two occurring at the constituent protuberances 9 of the local enlargements of the width of the bus 3. This “double print” technique could irrespectively be implemented and parameterised so as to make the width Lb of the bus 3 substantially equal to the width of the strip 5, as in the case in FIGS. 8 and 10.

In particular, the first printing step may be carried out so that the first layer of the collecting finger 2 is discontinuous at the zone 4 of the electrical connection to the bus 3. The first layer of the collecting finger 2 comprises at least two segments aligned in the first direction D1 having interposed between them a space “Ed” (FIGS. 9 and 13) in the first direction D1. The first and second screen-printing steps may especially be carried out so that the total width Lt of the bus 3 at a local enlargement is larger than the space Ed, this difference between the width Lt and the space Ed being larger than 100 microns and distributed, especially equally, on either side of the bus 3 along the first direction D1. Thus, each protuberance 9 extends along the first direction D1 across segments of collecting fingers 2 over a length referenced “Lc” larger than about 50 microns.

Moreover, in the context of a “double print” technique, the first and second screen-printing steps may be carried out so that the ratio of the length We in the second direction D2 of the local enlargement of the width of the bus 3 to the width Wd of the corresponding collecting finger 2 in the second direction D2 is higher than two.

Among the metallisation techniques capable of being used in the context of the invention, mention may be made, apart from screen printing, of: contactless methods such as inkjet printing or dispensing; and electro or electroless plating, which allow metals such as silver, nickel, copper and tin to be deposited.

It is possible to provide zones allowing a reliable electrical contact to be formed between the two printing levels independently of whether the two printing levels are misaligned. A reliable electrical contact is guaranteed even though the alignment precision of currently available screen-printing machines is typically about 15 microns.

During the manufacture of a photovoltaic module comprising a plurality of photovoltaic cells, a step is carried out in which a metal strip 5, which is especially made of copper, is electrically interconnected with the bus 3. This step is carried out so that the metal strip 5 at least partially covers the bus 3 while being mechanically and electrically connected to the latter, by an electrically conductive fastening means 6 such as a solder or adhesive conductor, over all or some of the length of the bus 3. The interconnection step and the metallisation step are preferably carried out so that the space Ed in the first direction D1 (between two segments of a discontinuous collecting finger 2 or between two segments of a first layer of a discontinuous collecting finger 2) is larger than the width Lr of the metal strip 5 along the first direction D1. The difference between the space Ed and the width Lr is advantageously larger than 200 microns and distributed, especially equally, on either side of the bus 3 along the first direction D1.

A photovoltaic module comprises a plurality of photovoltaic cells that are electrically connected to one another by way of at least one metal strip 5 that is interconnected with at least one bus 3 of the photovoltaic cells.

The principles described above are applicable to heterojunction or homojunction photovoltaic cells, whether they are monofacial or bifacial. In particular, just like the front side, the back side of a photovoltaic cell may also comprise electrically conductive metallisations such as described above.

The protuberances 9, even though they are portrayed as rectangles in the plane (D1, D2), may be any shape. In particular, any shape may be envisaged that allows an interconnection in a zone of dimension larger than those of the collecting fingers 2 in order to prevent the latter breaking under stress. However, this zone will preferably be planar in order to allow these stresses to be satisfactorily distributed. Likewise, the zones of contact between the two successive printed deposits are not necessarily rectangular in shape and may for example be tapered.

In a first example, the photovoltaic cell comprises a metallisation produced using a silver-based ink baked at a high temperature (800° C.). The step of screen printing the front side of the substrate 1 is carried out in a single step using the “simple print” technology (FIG. 12). The width Wd of the collecting fingers 2 is 100 μm. The width Lb of the buses 3 is 1.5 mm in order to allow copper metal strips 5 having a width Lr of 1.5 mm to be interconnected. The protuberances 9 are such that the length We is 200 μm and the total length Lt is 1.9 mm. Thus, the enlargement Le is of 200 μm on either side of the bus 3. The interconnection between the strip 5 and the bus 3 is achieved by soldering the copper strips coated with 20 μm of an SnPbAg alloy. The strips 5 never overlap the collecting fingers 2 of 100 μm width. In contrast they remain localised plumb with the enlargements 9, even in the case of a misalignment of 200 microns between the strips 5 and the buses 3. The additional shadowing associated with the enlargements of the bus 3 is almost zero.

In a second example, the photovoltaic cell comprises a metallisation produced using a silver-based ink baked at a high temperature (800° C.). The step of screen printing the front side of the substrate 1 is carried out in a single step using the “simple print” technology (FIG. 12). The width Wd of the collecting fingers 2 is 80 μm. The width Lb of the buses 3 is 0.8 mm in order to allow copper metal strips 5 having a width Lr of 1.5 mm to be interconnected. The protuberances 9 are such that the length We is 200 μm and the total length Lt is 1.8 mm (corresponding to 500 μm on either side of the bus of 800 μm). The interconnection of the copper strips 5 involves grooving the surface and adhesive bonding and they are coated with 1.3 μm of silver. The interconnection is formed by polymerising an adhesive filled with silver-based conductive particles. The copper strips 5 never overlap the collecting fingers 2 of 80 μm width. In contrast they remain localised plumb with the protuberances 9, even in the case of a misalignment of 150 microns between the strips 5 and the buses 3. The additional shadowing associated with the enlargements of the bus 3 is almost zero.

In a third example, a heterojunction photovoltaic cell is produced with a low-temperature process. The metallisations are formed with a silver-based ink baked at 200° C. The cell is bifacial, collecting fingers 2 being present on both the front and back sides of the substrate 1. The screen printing of the front side is of the “double print” type (FIG. 13). The width Wd of the front-side collecting fingers 2 is 90 μm. The first layer of the collecting fingers is discontinuous and a space Ed of 1.3 mm is provided. The second printing step allows the second layer of the collecting fingers 2 and the buses with their protuberances 9 to be formed. The passage from two thicknesses to one thickness of the collecting fingers 2 takes place in zones corresponding to the enlargements of the bus, thereby ensuring zones of higher resistance are not created. The width Lb of the bus 3 is 0.2 mm for interconnection of copper strips 5 of width Lr equal to 1.0 mm. The protuberances 9 are such that the length We is 300 μm and the total width Lt is equal to 1.6 mm (thus, Le is equal to 700 μm on either side of the bus 3). The zones in which the collecting fingers 2 have two layers are outside of the interconnection zones on which the copper strips 5 rest (the zone of length “Lc” is located outside of the space Ed). Thus, the copper strips 5 rest on planar zones at bus enlargements. These planar zones allow the strip 5 to remain parallel to the cell and the interconnection stresses to be regularly distributed. The screen printing of the back side is of the “single print” type with a bus width Wd equal to 110 μm. The width Lb of the buses is 0.2 mm in order to interconnect copper strips 5 having a width Lr of 1.5 mm. The protuberances 9 are configured so that We is equal to 300 μm and Lt is equal to 1.5 mm (corresponding to 650 μm on either side of the bus 3). The copper strips 5 are interconnected by adhesive bonding. The surface of the copper is grooved, in order to limit losses due to reflection from the strips 5, and coated with 1.3 μm of silver. The interconnection is formed by polymerising an adhesive 6 filled with silver-based conductive particles. On both the back and front sides of the cell, the copper strips 5 never overlap the collecting fingers of width Wd equal to 100 μm. In contrast, they remain localised plumb with the enlargements of the bus 3, even in the case of a misalignment of 150 microns between the strips 5 and the buses 3. The additional shadowing associated with the enlargements of the bus 3 is almost zero.

In a fourth example, the photovoltaic cell comprises metallisations produced using a silver-based ink, baked at a high temperature (800° C.). The step of screen printing the front side of the substrate 1 is carried out using the “dual print” technology (FIG. 13). The width Wd of the front-side collecting fingers 2 is 80 μm. The first layer of the discontinuous collecting fingers 2 contains a space Ed equal to 1.7 mm in the zones intended for the bus/metal strip interconnection. The absence of metallisation in the space Ed makes effective contact of the screen during the screen printing of the bus 3 possible, thereby allowing a well-controlled regular thickness to be deposited. The second screen-printing step provides for a bus 3 having a width of 1.4 mm to be printed in order to allow a copper strip 5 having a width of 1.5 mm to be interconnected.

The dimension We of the enlargements of the bus 3 is about 250 μm, and the total width Lt is about 2.1 mm, the dimension “Le” being equal to 350 μm on either side of the bus 3. The collecting finger 2 and the bus 3 make contact over a nominal length Lc equal to 200 μm. The interconnection between the strip 5 and the bus 3 is achieved by soldering the copper strip 5 coated with 20 μm of an SnPbAg alloy. The copper strips 5 thus never overlap the collecting fingers 2. In contrast they remain localised plumb with the enlargements of the bus 3 (said enlargements consisting of protuberances 9 having a size of 250 μm in D1) even in the case of a misalignment of 300 microns between the strips 5 and the buses 3. The additional shadowing associated with the enlargements of the bus 3 is almost zero.

Lastly, the supplementary advantages of the solution described above are essentially that it allows:
the risk of interconnection of the metal strip and the collecting fingers to be decreased or even negated, whether in the case of an unintentional offset Δ between the bus and the metal strip if the width of the metal strip Lr is substantially identical to the width Lb of the bus 3, or in the case of interconnection of a metal strip intentionally having a width Lr clearly larger than the width of the bus 3;
the interconnection between the metal strip 5 and the bus 3 to be formed on a planar surface, the metallisation containing no thickness irregularities in the interconnection zone; and
advantageous margins of error to be provided in the alignment of two printing operations, in the case of a “dual print” or “double print” technique.

1. Photovoltaic module comprising a plurality of photovoltaic cells,
each cell comprising at least one collecting finger oriented in a first elongation direction and at least one bus oriented in a second elongation direction making an angle to the first elongation direction,
the bus comprising, at a zone of electrical connection between the bus and the collecting finger, at least one local enlargement of a width of the bus along the first elongation direction,
wherein a ratio of a length in the second direction of the local enlargement of the width of the bus to a width of the corresponding collecting finger in the second direction is strictly higher than one, and
the photovoltaic cells being electrically connected to one another by way of at least one metal strip interconnected with the at least one bus of the photovoltaic cells,
wherein a total width of the bus at the local enlargement is strictly larger than a width of the metal strip along the first direction.

2. Photovoltaic module according to claim 1, which comprises a plurality of collecting fingers, wherein each collecting finger of said plurality of collecting fingers is electrically connected to the bus in the respective associated electrical connection zone, so that the bus electrically connects the collecting fingers to one another and between the electrical connection zones.

3. Photovoltaic module according to claim 2, wherein each of the electrical connection zones between the bus and the collecting fingers comprises a respective local enlargement of the width of the bus.

4. Photovoltaic module according to claim 2, wherein the total width of the bus at the local enlargement of any electrical connection zone is strictly higher than the width of the bus outside of the electrical connection zones.

5. Photovoltaic module according to claim 4, wherein the ratio of the width of the bus at the local enlargement of its width to the width of the bus outside of the electrical connection zones is higher than 1.25.

6. Photovoltaic module according to claim 4, wherein the difference between the width of the bus at a local enlargement of its width and the width outside of the electrical connection zones is larger than 400 microns.

7. Photovoltaic module according to claim 2, wherein a given enlargement of the bus is associated, on a given side of the bus, along the first direction, with a single collecting finger.

8. Photovoltaic module according to claim 1, wherein a length in the second direction of the local enlargement of the width of the bus is larger than or equal to 150 microns.

9. Photovoltaic module according to claim 1, wherein the ratio of the length in the second direction of the local enlargement of the width of the bus to the width of the corresponding collecting finger in the second direction is higher than two.

10. Photovoltaic module according to claim 1, wherein the metal strip is mechanically and electrically connected to at least one bus of the photovoltaic cells by an electrically conductive fastening means over all or some of the length of the bus.

11. Photovoltaic module according to claim 1, wherein the metal strip is oriented along the second direction over the entire length of a substrate on which the collecting fingers and said at least one bus are formed, and beyond the substrate in order to allow a plurality of photovoltaic cells to be electrically connected to one another.

12. Photovoltaic module according to claim 1, wherein the difference between the total width of the bus at a local enlargement of the metal strip is larger than 400 microns.

13. Manufacturing process of a photovoltaic module according to claim 1, comprising:
metallizing a substrate so as to form said at least one collecting finger and said at least one bus, then
interconnecting said at least one metal strip and said at least one bus of the photovoltaic cells.

14. Manufacturing process according to claim 13, wherein, the metallizing step comprises conjointly forming said at least one collecting finger and said at least one bus.

15. Manufacturing process according to claim 13, wherein the metallizing step comprises:
a first step of producing only said at least one collecting finger on the substrate, and
a second step of producing only said at least one bus on the substrate and covering a portion of the collecting finger in the electrical connection zone.

16. Manufacturing process according to claim 15, wherein the first step is carried out so that said at least one collecting finger is discontinuous, interrupted at its zone of electrical connection to said at least one bus and comprises at least two segments aligned in the first direction having interposed between them a space in the first direction.

17. Manufacturing process according to claim 16, wherein the first and second steps are carried out so that the total width of the bus at the local enlargement is larger than the space between two segments of collecting finger.

18. Manufacturing process according to claim 15, wherein the first and second steps are carried out so that the difference between the width of the collecting finger and the length in the second direction of the local enlargement of the bus is larger than 100 microns.

19. Manufacturing process according to claim 13, wherein the metallizing step comprises:
a first step of producing a first layer of said at least one collecting finger on the substrate, and
a second step of conjointly forming the following:
said at least one bus on the substrate and covering a portion of the first layer of the collecting finger in the electrical connection zone; and
a second layer of said at least one collecting finger on its first layer.

20. Manufacturing process according to claim 19, wherein the first step is carried out so that the first layer of the collecting finger is discontinuous at the zone of electrical connection to said at least one bus, and comprises at least two segments aligned in the first direction having interposed between them a space in the first direction.

21. Manufacturing process according to claim 20, wherein the first and second steps are carried out so that the total width of the bus at a local enlargement is larger than the space.

22. Manufacturing process according to claim 19, wherein the first and second steps are carried out so that the ratio of the length in the second direction of the local enlargement of the width of the bus to the width of the corresponding collecting finger in the second direction is higher than two.
